(19) United States
(12) Patent Application Publication
(10) Pub. No.: US 2022/0334979 A1
(43) Pub. Date: Oct. 20, 2022

(54) Crossbar Circuits And Methods For External Communication With Logic In Integrated Circuits

(71) Applicant: Intel Corporation, Santa Clara, CA (US)

(72) Inventors: Sreedhar Ravipalli, Cupertino, CA (US); Mahesh Kumashikar, Bangalore (IN); Md Altaf Hossain, Portland, OR (US); Ankireddy Nalamalpu, Portland, OR (US)

(73) Assignee: Intel Corporation, Santa Clara, CA (US)

(21) Appl. No.: 17/853,772

(22) Filed: Jun. 29, 2022

(51) Int. Cl. G06F 12/121

(52) U.S. Cl. CPC G06F 12/121; G06F 2212/7201

(57) ABSTRACT

An integrated circuit includes logic circuits, first buffer circuits coupled to external ports of the integrated circuit, second buffer circuits that are each coupled to one of the logic circuits, and a crossbar circuit coupled to the first and the second buffer circuits. The crossbar circuit is configurable to provide data transfer between the logic circuits and the external ports of the integrated circuit through the first buffer circuits and the second buffer circuits.

### FIELD OF THE DISCLOSURE

The present disclosure relates to electronic circuit systems, and more particularly, to crossbar circuits and methods for external communication with logic in integrated circuits.

### BACKGROUND

Configurable logic integrated circuits can be configured by users to implement desired custom logic functions. In a typical scenario, a logic designer uses computer-aided design tools to design a custom circuit design. When the design process is complete, the computer-aided design tools generate configuration data. The configuration data is then loaded into configuration memory elements that configure configurable logic circuits in the integrated circuit to perform the functions of the custom circuit design. Configurable logic integrated circuits can be used for co-processing in big-data or fast-data applications. For example, configurable logic integrated circuits may be used in application acceleration tasks in a datacenter and may be reprogrammed during datacenter operation to perform different tasks.

### BRIEF DESCRIPTION OF THE DRAWINGS

FIG. 1 is a diagram that illustrates a circuit system that includes a processing integrated circuit (IC) and a storage circuit.

FIG. 2 is a diagram that illustrates further details of the interface circuit of FIG. 1.

FIG. 3 is a diagram that illustrates an example of a server computer that includes an infrastructure processing system (IPS), a host system, and one or more memory devices.

FIG. 4 is a diagram of an illustrative programmable (i.e., configurable) logic integrated circuit (IC) that may be programmed according to a user design to implement the processing IC of FIG. 1.

FIG. 5 shows an illustrative circuit design system that can perform functions disclosed herein.

### DETAILED DESCRIPTION

A server computer in a datacenter can include one or more host processors and one or more coprocessors that function as acceleration devices. The host processor may be tasked to perform a pool of jobs/tasks. In order to improve the speed at which these tasks are performed, one or more of the coprocessor integrated circuit (IC) dies can be used to perform a subset of the pool of tasks. The host processor can send acceleration requests to one of the coprocessor IC dies. The coprocessor IC die functions as an accelerator device.

Hardware acceleration devices may be used for co-processing in big-data, fast-data, or high performance compute (HPC) applications in one or more server computers in a datacenter. Accelerator devices can, for example, be used in server computers to perform networking functions for packets of data that are transmitted to the server computers through one or more networks. By offloading acceleration functions (e.g., computationally intensive tasks) from a host processor to one or more coprocessors that function as acceleration devices, the host processor is freed up to perform other critical processing tasks. The use of hardware accelerators can therefore help deliver improved speed, latency, power efficiency, and flexibility for acceleration functions, such as cryptography, end-to-end cloud computing, networking, storage, artificial intelligence, autonomous driving, virtual reality, augmented reality, gaming, and other data-centric applications. An acceleration device may be a programmable logic integrated circuit (IC), such as a field programmable gate array (FPGA) that contains soft logic circuitry programmed to perform acceleration functions for a host processor, an application specific IC (ASIC) that contains hard logic circuitry designed to perform acceleration functions for a host processor, or an IC that combines soft and hard logic circuitry.

This disclosure discusses circuit systems that can be implemented in integrated circuit devices, including configurable (programmable) logic devices such as field programmable gate arrays (FPGAs). As discussed herein, an integrated circuit (IC) may include hard logic and/or soft logic. As used herein, “hard logic” generally refers to circuits in an integrated circuit device that are not programmable by an end user. The circuits in an integrated circuit device (e.g., in a configurable IC) that are programmable by the end user are referred to as “soft logic.”

A programmable logic IC can communicate with external devices that are outside the programmable logic IC using transceiver circuits. The transceiver circuits are typically next to one side of the programmable logic IC and have fixed connections to adjacent sectors of programmable logic circuits. When a programmable logic IC is implemented as an accelerator device, portions of a circuit design for the programmable logic IC that need frequent access to the external devices through external ports are often placed in sectors of programmable logic circuits that are next to the transceiver circuits to increase data transfer speeds and bandwidth between these portions of the circuit design and the external devices. However, constraining placement of these portions of the circuit design to sectors that are next to the transceiver circuits can substantially limit flexibility in how the circuit design can be placed in the IC. In some circuit designs for a programmable logic IC, logic circuits may need to be relocated (e.g., during reconfiguration) to different portions of the programmable logic IC fabric to provide optimal usage of the programmable logic resources. The fixed connections between the transceiver circuits and the adjacent sectors of programmable logic circuits may cause challenges to reconfiguring some circuit designs, and at the same time, maintaining data rate throughput.

According to some examples disclosed herein, an integrated circuit (IC) includes sectors of logic circuits and an interface circuit that allows data to be routed between external devices and any of the sectors of logic circuits, including sectors that are not next to the interface circuit. The interface circuit can, for example, include first buffer circuits, second buffer circuits, and a crossbar switch circuit. Data exchanged with the external devices can be stored in one or more of the first buffer circuits. Data exchanged with the logic circuits in the sectors can be stored in one or more of the second buffer circuits. The crossbar switch circuit can be programmed to couple any of the first buffer circuits to any of the second buffer circuits to allow fast data transfer between the external devices and the logic circuits in any of the sectors. As a result, logic circuits in a circuit design for the IC that perform high bandwidth or high-speed computations (e.g., for networking functions or application processing) can be spread across the sectors of the IC (or across only the peripheral sectors), instead of only being located next to the transceiver circuits and/or next to an edge of the IC.

One or more specific examples are described below. In an effort to provide a concise description of these examples, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

Throughout the specification, and in the claims, the term “connected” means a direct electrical connection between the circuits that are connected, without any intermediary devices. The term “coupled” means either a direct electrical connection between circuits or an indirect electrical connection through one or more passive or active intermediary devices. For example, a sending circuit and a receiving circuit can be coupled together through a buffer circuit or a driver circuit that transmits a signal from the sending circuit to the receiving circuit. The term “circuit” may mean one or more passive and/or active electrical components that are arranged to cooperate with one another to provide a desired function.

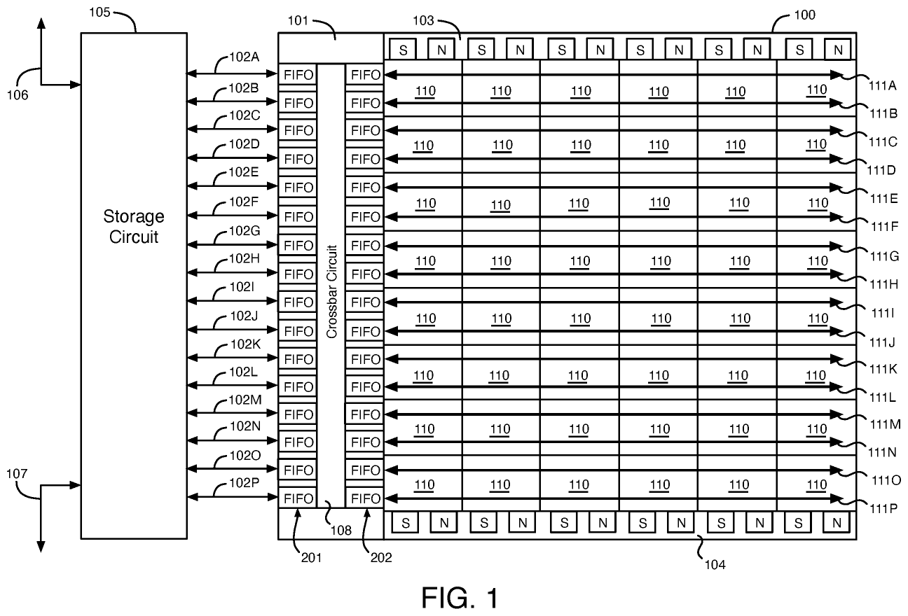

FIG. 1 is a diagram that illustrates a circuit system that includes a processing integrated circuit (IC) 100 and a storage circuit 105. Storage circuit 105 includes storage circuits at different storage locations. The processing IC 100 and the storage circuit 105 are in separate integrated circuit dies in the example of Figure (FIG. 1. The processing IC 100 can be, for example, a programmable logic integrated circuit (IC), such as a field programmable gate array (FPGA), or another type of processing IC, such as a microprocessor, a central processing unit (CPU), or a graphics processing unit (GPU). IC 100 and the IC die containing the storage circuit 105 can be in the same integrated circuit package or coupled to the same circuit board.

The processing IC 100 includes interface circuit 101, sectors 110 of logic circuits, network-on-chip (NOC) circuits 103-104, and 16 interconnects (e.g., conductors and buffer circuits) 111A-111P. Storage circuit 105 communicates with external devices, such as host processor and acceleration devices, through networks 106-107. The interface circuit 101 is coupled to the storage circuit 105 and communicates with the storage circuit 105 through 16 external conductors 102A-102P. External conductors 102A-102P can include, for example, conductive bumps or balls, and/or conductors in a package substrate, interconnection bridge, or interposer. Interface circuit 101 is next to a left edge of IC 100 in the example of FIG. 1. Interface circuit 101 includes first-in-first-out (FIFO) buffer circuits 201-202 and a crossbar circuit 108. Interface circuit 101 is coupled to, and communicates with, logic circuits in sectors 110 through interconnects 111A-111P. 48 sectors 110 of logic circuits arranged in 8 rows and 6 columns are shown in FIG. 1 merely as an example. It should be understood that a processing IC die as disclosed herein can have any number of sectors of logic circuits that are arranged in any fashion. If processing IC 100 is a programmable logic IC, such as an FPGA, each of the sectors 110 can include an array (or blocks) of programmable logic circuits arranged, for example, in rows and columns within the sector. NOC circuits 103-104 include north (N) and south (S) router circuits that are configurable to route signals vertically across IC 100 through sectors 110 using vertical interconnects (not shown) that are configurable to be coupled to the horizontal interconnects 111A-111P.

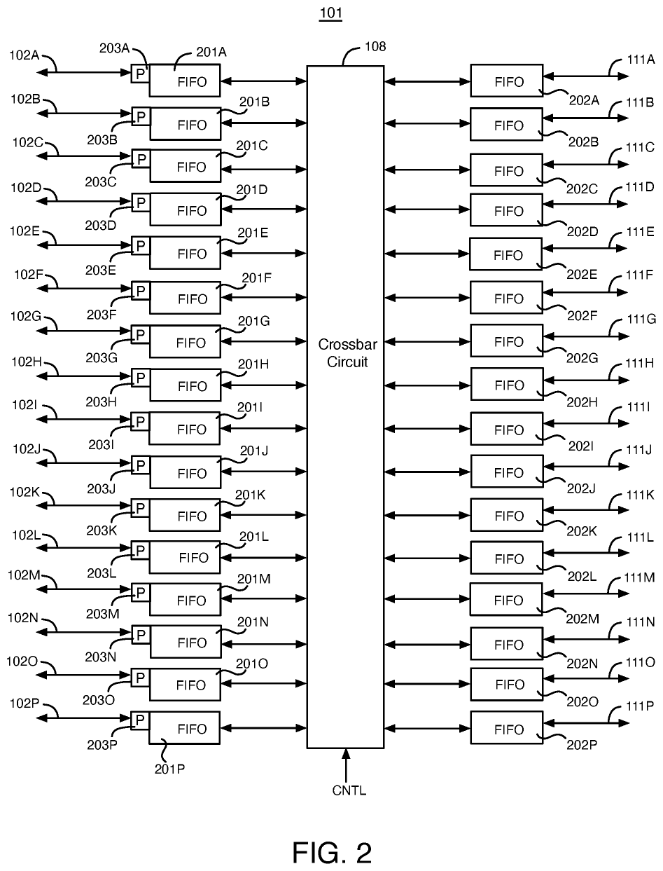

FIG. 2 is a diagram that illustrates further details of the interface circuit 101 of FIG. 1. In the example of FIG. 2, interface circuit 101 includes a first set of 16 first-in-first-out (FIFO) buffer circuits 201A-201P, crossbar circuit 108, and a second set of 16 FIFO buffer circuits 202A-202P. 16 FIFO buffer circuits 201A-201P and 16 FIFO buffer circuits 202A-202P are shown in FIG. 2 merely as an example. It should be understood that an interface circuit as disclosed herein can have any number of buffer circuits. Each of the 16 FIFO buffer circuits 201A-201P is coupled to, and in bidirectional communication with, the crossbar circuit 108 through one or more conductors. In addition, each of the 16 FIFO buffer circuits 202A-202P is coupled to, and in bidirectional communication with, the crossbar circuit 108 through one or more conductors. Each of the conductors or set of conductors coupled to one of the FIFO buffer circuits 201-202 and to the crossbar circuit 108 is shown as a two-way arrow in FIG. 2.

The FIFO buffer circuits 201A-201P are coupled to external ports 203A-203P, respectively, of IC 100. For example, FIFO buffer circuit 201A is coupled to external port 203A, and FIFO buffer circuit 201P is coupled to external port 203P. External ports 203A-203P of the IC 100 are coupled to external conductors 102A-102P, respectively. The external ports 203 can include, for example, conductive pads or conductive pins. In some examples, external ports 203 can include input and output buffer circuits coupled to the pads or pins. The FIFO buffer circuits 201A-201P are coupled to, and in bidirectional communication with, the storage circuit 105 through external conductors 102A-102P and external ports 203A-203P, respectively, as shown in FIGS. 1-2.

The FIFO buffer circuits 202A, 202B, 202C, 202D, 202E, 202F, 202G, 202H, 202I, 202J, 202K, 202L, 202M, 202N, 202O, and 202P are coupled to, and in bidirectional communication with, the 8 rows of sectors 110 of logic circuits through on-die interconnects 111A, 111B, 111C, 111D, 111E, 111F, 111G, 111H, 111I, 111J, 111K, 111L, 111M, 111N, 111O, and 111P, respectively, shown in FIG. 1. Two sets of the interconnects 111A-111P are coupled to the sectors 110 of logic circuits in each of the 8 rows of sectors 110. Alternatively, the FIFO buffer circuits 202A-202P can be only coupled to, and in bidirectional communication with, the sectors 110 of logic circuits that are next to two, three, or four sides of the core logic region of the IC die 100, such as the sectors in the first row, the sectors in the eight row, and the sectors in the first column of logic circuits that are next to interface circuit 101.

The crossbar circuit 108 is programmable to couple any one or more of the FIFO buffer circuits 201A-201P to any one or more of the FIFO buffer circuits 202A-202P based on, for example, the values of input control signals CNTL. As an example, the crossbar circuit 108 can be programmed to couple FIFO buffer circuit 201A to any one or more of the FIFO buffer circuits 202A-202P. As another example, the crossbar circuit 108 can be programmed to couple FIFO buffer circuit 201B to any one or more of the FIFO buffer circuits 202A-202P. As yet another example, the crossbar circuit 108 can be programmed to couple FIFO buffer circuit 201C to any one or more of the FIFO buffer circuits 202A-202P. The crossbar circuit 108 can, for example, include an array of tristate buffer circuits that are controllable by control signals CNTL to couple any of the FIFO buffer circuits 201A-201P to any of the FIFO buffer circuits 202A-202P through the corresponding conductors.

The interface circuit 101 of FIGS. 1-2 can be configured (e.g., by control signals CNTL) to bidirectionally or unidirectionally exchange data between any of the storage locations in storage circuit 105 and any of the sectors 110 of logic circuits in any of the rows of sectors 110 in IC 100. As an example, crossbar circuit 108 can be programmed to exchange data bidirectionally or unidirectionally between a first storage location in storage circuit 105 and one or more sectors 110 of logic circuits in the eighth (bottom) row of sectors 110 by coupling together FIFO buffer circuit 201A and FIFO buffer circuit 202O or 202P. In this example, data stored in the first storage location can be transmitted to one or more of the sectors 110 in the eighth row through conductor 102A, port 203A, FIFO buffer circuit 201A, crossbar circuit 108, FIFO buffer circuit 202O and/or 202P, and interconnects 111O and/or 111P. Data stored in one or more sectors in the eight row of sectors 110 can be transmitted to the first storage location in storage circuit 105 through interconnects 111O and/or 111P, FIFO buffer circuit 2020 and/or 202P, crossbar circuit 108, FIFO buffer circuit 201A, port 203A, and conductor 102A.

As another example, crossbar circuit 108 can be programmed to exchange data bidirectionally or unidirectionally between a second storage location in storage circuit 105 and one or more sectors 110 of logic circuits in the fourth row (from the top) of sectors 110 by coupling together FIFO buffer circuit 201D and FIFO buffer circuit 202G or 202H. In this example, data stored in the second storage location in storage circuit 105 can be transmitted to one or more sectors 110 in the fourth row through conductor 102D, port 203D, FIFO buffer circuit 201D, crossbar circuit 108, FIFO buffer circuit 202G and/or 202H, and interconnects 111G and/or 111H. Data stored in one or more sectors in the fourth row of sectors 110 can be transmitted to the second storage location in storage circuit 105 through interconnects 111G and/or 111H, FIFO buffer circuit 202G and/or 202H, crossbar circuit 108, FIFO buffer circuit 201D, port 203D, and conductor 102D.

As yet another example, crossbar circuit 108 can be programmed to exchange data bidirectionally or unidirectionally between a third storage location in storage circuit 105 and one or more sectors 110 of logic circuits in the first (top) row of sectors 110 by coupling together FIFO buffer circuit 201P and FIFO buffer circuit 202A or 202B. In this example, data stored in the third storage location in storage circuit 105 can be transmitted to one or more sectors 110 in the first row through conductor 102P, port 203P, FIFO buffer circuit 201P, crossbar circuit 108, FIFO buffer circuit 202A and/or 202B, and interconnects 111A and/or 111B. Data stored in one or more sectors in the first row of sectors 110 can be transmitted to the third storage location in storage circuit 105 through interconnects 111A and/or 111B, FIFO buffer circuit 202A and/or 202B, crossbar circuit 108, FIFO buffer circuit 201P, port 203P, and conductor 102P.

The interface circuit 101 of IC 100 enables logic circuits in a circuit design for IC 100 to be flexibility placed in any suitable sector 110 of logic circuits, without requiring that some portions of the circuit design that require high bandwidth or high-speed connections with an external device be placed next to an edge of IC 100. Interface circuit 101 provides several lower bandwidth streaming interfaces through FIFO buffer circuits 201A-201P, crossbar circuit 108, and FIFO buffer circuits 202A-202P. The interface circuit 101 enables external ports 203A-203P of IC die 100 that are coupled to conductors 102A-102P to be seamlessly coupled to (and in communication with) any sector 110 of logic circuits in the core logic region of the IC die 100 (including peripheral sectors 110) in a non-blocking configuration. As a result, logic circuits in a circuit design for IC 100 that perform high bandwidth or high-speed computations (e.g., for networking functions or application processing) can be spread across the sectors 110 in the core logic region of the IC die 100 (or across the peripheral sectors 110). Also, communication between external devices and the logic circuits in the circuit design for IC 100 that perform the high bandwidth or high-speed computations can be spread across the IC die 100 using the signal paths through interconnects 111 and interface circuit 101.

Interface circuit 101 alleviates congestion in the sectors 110 of logic circuits, because interface circuit 101 and interconnects 111 provide direct signal paths from logic circuits in each of the sectors 110 to external ports 203 coupled to external devices (e.g., through storage circuit 105), without requiring routing through other sectors 110. In addition, logic circuits in a circuit design for IC 100 can be relocated to different sectors 110 of logic circuits, because interface circuit 101 and interconnects 111 provide the direct signal paths from logic circuits in each of the sectors 110 to the external ports 203 coupled to the external devices. Interface circuit 101 allows at least some of the logic circuits in a circuit design for IC 100 that are experiencing congestion (e.g., due to having high bandwidth or high-speed data connections with external devices) to be replaced and rerouted to sectors 110 that are in an area of the IC 100 that has lower data traffic.

Interface circuit 101 also supports multiple logical channels through the FIFO buffer circuits 201A-201P and 202A-202P and the crossbar circuit 108 that can be configured to provide flexibility and optimal bandwidth between external devices and the sectors 110 of logic circuits. The interface circuit 101 can, for example, be non-arbitrated to enable easier analysis of the system performance. Thus, interface circuit 101 does not require an arbiter that is used to resolve conflicting requests for data transfers.

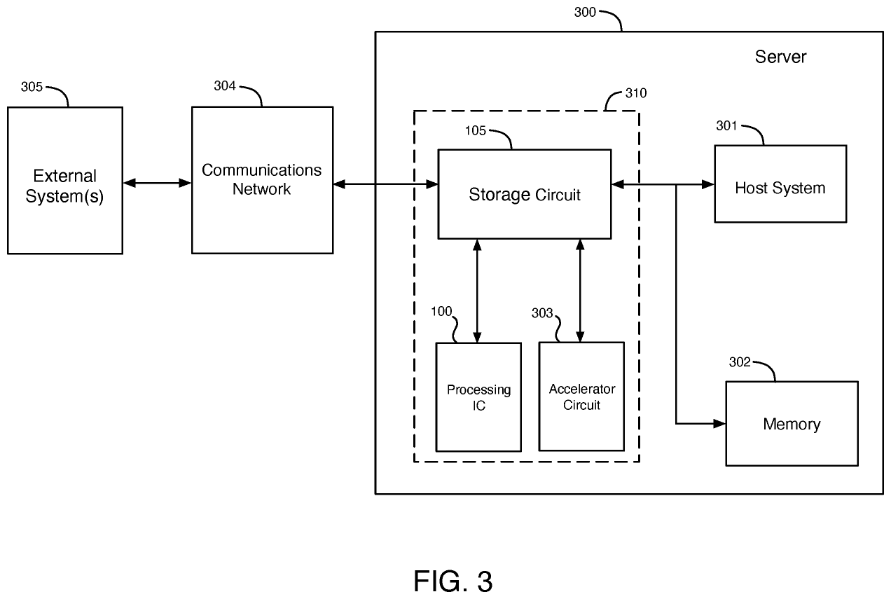

FIG. 3 is a diagram that illustrates an example of a server computer 300 that includes an infrastructure processing system (IPS) 310, a host system 301, and one or more memory devices 302. In the example of FIG. 3, the IPS 310 includes the storage circuit 105, processing IC die 100, and an accelerator circuit 303. IPS 310 can be, for example, a multi-chip integrated circuit package or a circuit board coupled to storage circuit 105, processing IC 100, and accelerator circuit 303. The processing IC 100 and the accelerator circuit 303 are coupled to the storage circuit 105. FIG. 3 also shows one or more external system(s) 305 and a communications network 304. The external system(s) 305 can transmit packets of data to the storage circuit 105 through the communications network 304.

The processing IC 100 and the accelerator circuit 303 can, for example, process the packets of data according to network protocol standards. The processing IC 100 and the accelerator circuit 303 can, for example, perform networking functions that are defined according to one or more of the layers of the Open Systems Interconnection (OSI) model. External systems 305 and host system 301 can generate packets of data that are transmitted to accelerator circuit 303 and/or to processing IC 100 for processing via storage circuit 105. The results of the processing operations performed by processing IC 100 and accelerator circuit 303 using the packets of data, or portions of the packets of data such as headers, can be provided to and stored in storage circuit 105 as disclosed herein, and then transmitted from storage circuit 105 to external systems 305, host system 301, and/or to memory devices 302. Packets of data stored in storage circuit 105 can be transmitted to external system(s) 305 through communications network 304.

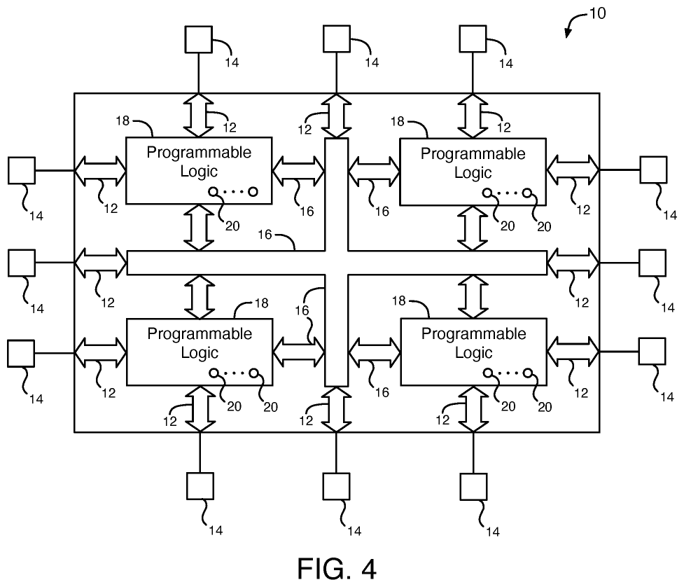

FIG. 4 is a diagram of an illustrative programmable (i.e., configurable) logic integrated circuit (IC) 10 that may be programmed according to a user design to implement processing IC 100 of FIG. 1. As shown in FIG. 4, programmable logic integrated circuit 10 has input-output circuitry 12 for driving signals off of IC 10 and for receiving signals from other devices via input-output pads 14. Interconnection resources 16 such as global, regional, and local vertical and horizontal conductive lines and buses can be used to route signals on IC 10. Interconnection resources 16 include fixed interconnects (conductive lines) and programmable interconnects (i.e., programmable connections between respective fixed interconnects). Programmable logic circuitry 18 may include combinational and sequential logic circuitry. Programmable logic circuitry 18 can be configured to perform custom logic functions.

Programmable logic IC 10 contains memory elements 20 that can be loaded with configuration data using pads 14 and input-output circuitry 12. Once loaded, the memory elements 20 may each provide a corresponding static control output signal that controls the state of an associated logic component in programmable logic circuitry 18. Typically, the memory element output signals are used to control the gates of field-effect transistors. In the context of programmable integrated circuits, the memory elements 20 store configuration data and are sometimes referred to as configuration random-access memory (CRAM) cells. The configuration data programs the programmable logic 18 to perform the custom logic functions according to the user design.

It can be a significant undertaking to design and implement a user (custom) logic circuit design for an integrated circuit (IC), such as a programmable logic IC. Logic designers therefore generally use logic design systems based on computer-aided-design (CAD) tools to assist them in designing circuits for ICs. A logic design system can help a logic designer design and test complex circuits for a system. When a design is complete, the logic design system may be used to generate configuration data for electrically programming the appropriate programmable logic IC according to the user design.

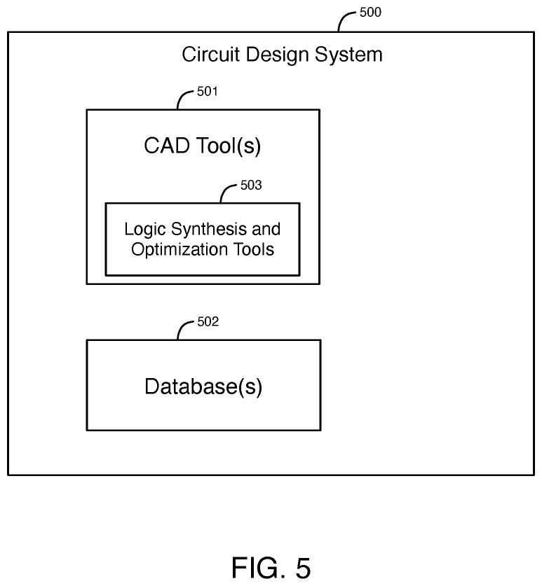

An illustrative circuit design system 500 is shown in FIG. 5. Any of the systems and methods disclosed herein can be implemented by the circuit design system 500. Circuit design system 500 can be implemented on integrated circuit design computing equipment. Circuit design system 500 can, for example, include one or more networked computers with processors, memory, mass storage, input/output devices, etc. System 500 can, for example, be based on one or more processors, such as processors in personal computers, workstations, etc. The processor(s) can be linked using a network (e.g., a local or wide area network). Memory in these computers or external memory and storage devices can be used to store instructions and data. Circuit design system 500 can be used to create a circuit design for any type of IC, such as a programmable logic IC.

Software-based components such as computer-aided design (CAD) tools 501 and databases 502 reside on system 500. During operation, executable software such as the software of computer aided design tools 501 runs on the processor(s) of system 500.

Databases 502 are used to store data for the operation of system 500. In general, software and data may be stored in non-transitory computer readable storage media (e.g., tangible computer readable storage media).

CAD tools 501 can include logic synthesis and optimization tools 503 that perform systems and methods disclosed herein. Once the functional operation of the circuit design has been determined to be satisfactory, the logic synthesis and optimization tools 503 can generate a gate-level netlist of the circuit design, for example, using gates from a particular library pertaining to a targeted process supported by a foundry that has been selected to produce the integrated circuit. Alternatively, the logic synthesis and optimization tools 503 can generate a gate-level netlist of the circuit design using gates of a targeted programmable IC (i.e., in the logic and interconnect resources of a particular programmable IC product or product family).

The logic synthesis and optimization tools 503 can optimize the circuit design by making appropriate selections of hardware to implement different logic functions in the circuit design based on the circuit design data and constraint data entered by the logic designer. As an example, the logic synthesis and optimization tools 503 can perform multi-level logic optimization and technology mapping based on the length of a combinational path between registers in the circuit design and corresponding timing constraints that were entered by the logic designer.

After logic synthesis and optimization, the circuit design system 500 can use tools such as placement, routing, and physical synthesis tools to perform physical design steps (i.e., layout synthesis operations). These tools can be used to determine where to place each gate of the gate-level netlist. These tools create orderly and efficient implementations of circuit designs for any targeted integrated circuit (e.g., for a given programmable integrated circuit such as a field programmable gate array (FPGA)).

Software stored on the non-transitory computer readable storage media can be executed on system 500. When the software of system 500 is installed, the storage of system 500 has instructions and data that cause the computing equipment in system 500 to execute various methods (processes). When performing these processes, the computing equipment is configured to implement the functions of circuit design system 500.

The computer aided design (CAD) tools 501, some or all of which are sometimes referred to collectively as a CAD tool, a circuit design tool, or an electronic design automation (EDA) tool, can be provided by a single vendor or by multiple vendors. Tools 501 can be provided as one or more suites of tools (e.g., a compiler suite for performing tasks associated with implementing a circuit design in a programmable IC) and/or as one or more separate software components (tools). Database(s) 502 can include one or more databases that are accessed only by a particular tool or tools and can include one or more shared databases. Shared databases can be accessed by multiple tools. For example, a first tool can store data for a second tool in a shared database. The second tool can access the shared database to retrieve the data stored by the first tool. This allows one tool to pass information to another tool. Tools can also pass information between each other without storing information in a shared database if desired.

In general, software and data for performing any of the functions disclosed herein can be stored in non-transitory computer readable storage media. Non-transitory computer readable storage media is tangible computer readable storage media that stores data for a significant period of time, as opposed to media that only transmits propagating electrical signals (e.g., wires). The software code may sometimes be referred to as software, data, program instructions, instructions, or code. The non-transitory computer readable storage media can, for example, include computer memory chips, non-volatile memory such as non-volatile random-access memory (NVRAM), one or more hard drives (e.g., magnetic drives or solid state drives), one or more removable flash drives or other removable media, compact discs (CDs), digital versatile discs (DVDs), Blu-ray discs (BDs), other optical media, and floppy diskettes, tapes, or any other suitable memory or storage device(s).

Additional examples are now described. Example 1 is an integrated circuit comprising: logic circuits; first buffer circuits coupled to external ports of the integrated circuit; second buffer circuits, wherein each of the second buffer circuits is coupled to one of the logic circuits; and a crossbar circuit coupled to the first and the second buffer circuits, wherein the crossbar circuit is configurable to provide data transfer between the logic circuits and the external ports of the integrated circuit through the first buffer circuits and the second buffer circuits.

In Example 2, the integrated circuit of Example 1 can optionally include, wherein the logic circuits comprise programmable logic circuits that are arranged in rows of sectors, wherein each of the second buffer circuits is coupled to one of the rows of the sectors, and wherein the crossbar circuit is configurable to provide data transfer between the sectors of the programmable logic circuits in the rows and the external ports.

In Example 3, the integrated circuit of any one of Examples 1-2 can optionally include, wherein each of the first buffer circuits is a first-in-first-out buffer circuit.

In Example 4, the integrated circuit of any one of Examples 1-3 can optionally include, wherein each of the second buffer circuits is a first-in-first-out buffer circuit.

In Example 5, the integrated circuit of any one of Examples 1-4 can optionally include, wherein the crossbar circuit is configurable to provide data transfer between the logic circuits and the external ports in a non-blocking configuration.

In Example 6, the integrated circuit of any one of Examples 1-5 can optionally include, wherein the crossbar circuit couples the first buffer circuits that are selected based on control signals to the second buffer circuits that are selected based on the control signals.

In Example 7, the integrated circuit of any one of Examples 1-6 can optionally include, wherein the logic circuits are arranged in sectors that are next to at least three sides of a core logic region of the integrated circuit.

In Example 8, the integrated circuit of any one of Examples 1-7 can optionally include, wherein the crossbar circuit is configurable to provide bidirectional data transfers between the logic circuits and the external ports through the first buffer circuits and the second buffer circuits.

Example 9 is a circuit system comprising: a first integrated circuit comprising a storage circuit; and a second integrated circuit comprising logic circuits, first buffer circuits coupled to the storage circuit, second buffer circuits coupled to the logic circuits, and a crossbar circuit coupled to the first and the second buffer circuits, wherein the crossbar circuit is configurable to couple the first buffer circuits to the second buffer circuits to provide signal paths between the logic circuits and the storage circuit.

In Example 10, the circuit system of Example 9 can optionally include, wherein the logic circuits are arranged in rows in the second integrated circuit, wherein each of the second buffer circuits is coupled to one of the rows through an interconnect, and wherein the crossbar circuit is configurable to provide signal paths between the rows of the logic circuits and the storage circuit.

In Example 11, the circuit system of any one of Examples 9-10 can optionally include, wherein the logic circuits are programmable logic circuits that are configurable with configuration data.

In Example 12, the circuit system of any one of Examples 9-11 can optionally include, wherein at least one of the first buffer circuits is a first-in-first-out buffer circuit, and wherein at least one of the second buffer circuits is a first-in-first-out buffer circuit.

In Example 13, the circuit system of any one of Examples 9-12 can optionally include, wherein the crossbar circuit is configurable to transfer data from the logic circuits to the storage circuit through the second buffer circuits, the crossbar circuit, and the first buffer circuits.

In Example 14, the circuit system of any one of Examples 9-13 can optionally include, wherein the crossbar circuit is configurable to bidirectionally transfer data between the storage circuit and the logic circuits through the first buffer circuits, the crossbar circuit, and the second buffer circuits.

In Example 15, the circuit system of any one of Examples 9-14 can optionally include, wherein the crossbar circuit couples the first buffer circuits to the second buffer circuits that are selected based on control signals.

Example 16 is a method for providing data transfers in a processing integrated circuit, the method comprising: transferring first data from external ports of the processing integrated circuit to logic circuits through first buffer circuits, a crossbar circuit coupled to the first buffer circuits, and second buffer circuits coupled to the crossbar circuit, wherein the logic circuits, the first buffer circuits, the crossbar circuit, and the second buffer circuits are in the processing integrated circuit; and transferring second data from the logic circuits to the external ports through the second buffer circuits, the crossbar circuit, and the first buffer circuits.

In Example 17, the method of Example 16 further comprises: providing first signal paths from the first buffer circuits through the crossbar circuit to the second buffer circuits for transferring the first data.

In Example 18, the method of Example 17 further comprises: providing second signal paths from the second buffer circuits through the crossbar circuit to the first buffer circuits for transferring the second data.

In Example 19, the method of any one of Examples 16-18 can optionally include, wherein the first and the second buffer circuits are first-in-first-out buffer circuits.

In Example 20, the method of any one of Examples 16-19 can optionally include, wherein transferring the first data from the external ports of the processing integrated circuit to the logic circuits comprises transferring the first data to the logic circuits adjacent to first, second, and third sides of a region of logic circuits in the processing integrated circuit.

The foregoing description of the examples has been presented for the purpose of illustration. The foregoing description is not intended to be exhaustive or to be limiting to the examples disclosed herein. In some instances, features of the examples can be employed without a corresponding use of other features as set forth. Many modifications, substitutions, and variations are possible in light of the above teachings.

What is claimed is:

1. An integrated circuit comprising:
logic circuits;
first buffer circuits coupled to external ports of the integrated circuit;
second buffer circuits, wherein each of the second buffer circuits is coupled to one of the logic circuits; and
a crossbar circuit coupled to the first and the second buffer circuits, wherein the crossbar circuit is configurable to provide data transfer between the logic circuits and the external ports of the integrated circuit through the first buffer circuits and the second buffer circuits.

2. The integrated circuit of claim 1, wherein the logic circuits comprise programmable logic circuits that are arranged in rows of sectors, wherein each of the second buffer circuits is coupled to one of the rows of the sectors, and wherein the crossbar circuit is configurable to provide data transfer between the sectors of the programmable logic circuits in the rows and the external ports.

3. The integrated circuit of claim 1, wherein each of the first buffer circuits is a first-in-first-out buffer circuit.

4. The integrated circuit of claim 1, wherein each of the second buffer circuits is a first-in-first-out buffer circuit.

5. The integrated circuit of claim 1, wherein the crossbar circuit is configurable to provide data transfer between the logic circuits and the external ports in a non-blocking configuration.

6. The integrated circuit of claim 1, wherein the crossbar circuit couples the first buffer circuits that are selected based on control signals to the second buffer circuits that are selected based on the control signals.

7. The integrated circuit of claim 1, wherein the logic circuits are arranged in sectors that are next to at least three sides of a core logic region of the integrated circuit.

8. The integrated circuit of claim 1, wherein the crossbar circuit is configurable to provide bidirectional data transfers between the logic circuits and the external ports through the first buffer circuits and the second buffer circuits.

9. A circuit system comprising:
a first integrated circuit comprising a storage circuit; and
a second integrated circuit comprising logic circuits, first buffer circuits coupled to the storage circuit, second buffer circuits coupled to the logic circuits, and a crossbar circuit coupled to the first and the second buffer circuits,
wherein the crossbar circuit is configurable to couple the first buffer circuits to the second buffer circuits to provide signal paths between the logic circuits and the storage circuit.

10. The circuit system of claim 9, wherein the logic circuits are arranged in rows in the second integrated circuit, wherein each of the second buffer circuits is coupled to one of the rows through an interconnect, and wherein the crossbar circuit is configurable to provide signal paths between the rows of the logic circuits and the storage circuit.

11. The circuit system of claim 9, wherein the logic circuits are programmable logic circuits that are configurable with configuration data.

12. The circuit system of claim 9, wherein at least one of the first buffer circuits is a first-in-first-out buffer circuit, and wherein at least one of the second buffer circuits is a first-in-first-out buffer circuit.

13. The circuit system of claim 9, wherein the crossbar circuit is configurable to transfer data from the logic circuits to the storage circuit through the second buffer circuits, the crossbar circuit, and the first buffer circuits.

14. The circuit system of claim 9, wherein the crossbar circuit is configurable to bidirectionally transfer data between the storage circuit and the logic circuits through the first buffer circuits, the crossbar circuit, and the second buffer circuits.

15. The circuit system of claim 9, wherein the crossbar circuit couples the first buffer circuits to the second buffer circuits that are selected based on control signals.

16. A method for providing data transfers in a processing integrated circuit, the method comprising:
transferring first data from external ports of the processing integrated circuit to logic circuits through first buffer circuits, a crossbar circuit coupled to the first buffer circuits, and second buffer circuits coupled to the crossbar circuit, wherein the logic circuits, the first buffer circuits, the crossbar circuit, and the second buffer circuits are in the processing integrated circuit; and
transferring second data from the logic circuits to the external ports through the second buffer circuits, the crossbar circuit, and the first buffer circuits.

17. The method of claim 16 further comprising:
providing first signal paths from the first buffer circuits through the crossbar circuit to the second buffer circuits for transferring the first data.

18. The method of claim 17 further comprising:
providing second signal paths from the second buffer circuits through the crossbar circuit to the first buffer circuits for transferring the second data.

19. The method of claim 16, wherein the first and the second buffer circuits are first-in-first-out buffer circuits.

20. The method of claim 16, wherein transferring the first data from the external ports of the processing integrated circuit to the logic circuits comprises transferring the first data to the logic circuits adjacent to first, second, and third sides of a region of logic circuits in the processing integrated circuit.
